(19) United States
(12) Patent Application Publication
(10) Pub. No.: US 2021/0226097 A1
(43) Pub. Date: Jul. 22, 2021

(54) PACKAGE STRUCTURE AND METHOD FOR MANUFACTURING THE SAME

(71) Applicants: LITE-ON OPTO TECHNOLOGY (CHANGZHOU) CO., LTD., Changzhou City (CN); LITE-ON TECHNOLOGY CORPORATION, Taipei City (TW)

(72) Inventors: Kai-Chieh Liang, New Taipei City (TW); KUO-MING CHIU, New Taipei City (TW); Wei-Te Cheng, Taipei City (TW); Jie-Ting Tsai, New Taipei City (TW)

(21) Appl. No.: 17/152,720

(22) Filed: Jan. 19, 2021

Related U.S. Application Data
(60) Provisional application No. 62/963,195, filed on Jan. 20, 2020.
(60) Provisional application No. 63/065,547, filed on Aug. 14, 2020.

(30) Foreign Application Priority Data
Dec. 22, 2020 (CN) 202011531062.7

(51) Int. Cl. H01L 33/48; H01L 33/44; H01L 33/62; H01L 33/56

(52) U.S. Cl. CPC H01L 33/483; H01L 33/44; H01L 33/62; H01L 31/0203; H01L 2933/0025; H01L 2933/0066; H01L 2933/005; H01L 33/56

(57) ABSTRACT

A package structure and a method for manufacturing the same are provided. The package structure includes a substrate, a wall, a photonic device, an inner covering layer, and an outer covering layer. The wall is disposed on the substrate, and a space is formed between the substrate and the wall. The photonic device is accommodated in the space and disposed on the substrate. The photonic device includes a p-contact and an n-contact, and a gap is defined between the p-contact and the n-contact. The inner covering layer is disposed in the gap between the p-contact and the n-contact. The outer covering layer is covered on an upper surface of the substrate, an inner surface of the wall, and an outer surface of the photonic device.

### CROSS-REFERENCE TO RELATED PATENT APPLICATION

This application claims the benefits of priority to the U.S. Provisional Patent Applications of Ser. No. 62/963,195 filed on Jan. 20, 2020, and Ser. No. 63/065,547 filed on Aug. 14, 2020, and China Patent Application No. 202011531062.7, filed on Dec. 22, 2020 in People's Republic of China. The entire content of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure and a method for manufacturing the same, and more particularly to a package structure including a P-N junction having an inner covering layer therebetween and a method for manufacturing the same.

### BACKGROUND OF THE DISCLOSURE

Currently, in a conventional ultraviolet C light emitting diode (UVC LED) package structure, a P-N junction of the UVC LED is usually exposed to the outside, and dangling bonds are formed at the P-N junction, thereby affecting an overall stability of the package structure. In addition, die bonding adhesives is also a factor affecting the overall stability of the package structure. In general, gold-tin alloy and silver material are mostly adopted as a die bonding adhesive. However, the gold-tin alloy is required to be processed with a high temperature process and has relatively small heat conductivity coefficient. In addition, the silver material tends to migrate, causing short circuits.

Therefore, it has become an important issue in the industry to overcome the above-mentioned inadequacies through a structural design, so as to reduce a formation of the dangling bonds, thereby reducing the metal migration effect.

### SUMMARY OF THE DISCLOSURE

In response to the above-referenced technical inadequacies, the present disclosure provides a package structure and a method for manufacturing the same.

In one aspect, the present disclosure provides a package structure including a substrate, a wall, a photonic device, an inner covering layer, and an outer covering layer. The wall is disposed on the substrate, and a space is formed between the substrate and the wall. The photonic device is accommodated in the space, the photonic device is disposed on the substrate, and the photonic device includes a p-contact and an n-contact, in which a gap is defined between the p-contact and the n-contact. The inner covering layer is disposed in the gap between the p-contact and the n-contact. The inner covering layer covers the two opposite inner surfaces of the p-contact and the n-contact, respectively. The outer covering layer is disposed in the space and is covered on an upper surface of the substrate, an inner surface of the wall, and an outer surface of the photonic device.

In another aspect, the present disclosure provides a method for manufacturing a package structure including: providing a carrier, the carrier including a wall and two metal pads, the wall being arranged surrounding the two metal pads, and a groove being formed between the two metal pads; filling a first filling material in the groove, in which the first filling material is in a solid state; disposing a photonic device on the two metal pads, the photonic device including a p-contact and an n-contact, a gap is formed between the p-contact and the n-contact corresponding to the groove; conducting a first baking process and transforming the first filling material from a solid state to a molten state, so as to form an inner covering layer that covers a surface of the groove and a surface of the gap; providing a second filling material to fill into the wall; and conducting a second baking process, such that the second filling material forms an outer covering layer, and the outer covering layer is covered on an upper surface of the substrate, an inner surface of the wall, and an outer surface of the photonic device.

One of the beneficial effects of the present disclosure is that the package structure provided in the present disclosure can reduce a formation of the dangling bonds and prevent the metal migration effect from occurring through technical solutions of “the inner covering layer covering the two opposite inner surfaces of the p-contact and the n-contact, respectively” and “the outer covering layer covering the upper surface of the substrate, the inner surface of the wall and the outer surface of the photonic device”.

Another one of the beneficial effects of the present disclosure is that the method for manufacturing the package structure provided in the present disclosure can reduce a formation of the dangling bonds and prevent the metal migration effect from occurring through technical solutions of “conducting the first baking process and transforming the first filling material from a solid state to a molten state to form the inner covering layer, the inner covering layer covering the surface of the groove and the surface of the gap” and “conducting the second baking process, such that the second filling material forms the outer covering layer, and the outer covering layer is covered on the upper surface of the substrate, the inner surface of the wall, and the outer surface of the photonic device”.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings in which:

FIG. 1 is a schematic view of a package structure in one implementation according to the present disclosure.

FIG. 2 is a schematic view showing the package structure shown in FIG. 1 and a lens component according to the present disclosure.

FIG. 3 is a schematic view of the package structure in another implementation according to the present disclosure.

FIG. 4 is a schematic view illustrating the package structure shown in FIG. 1, when formed, being filled with a first filling material according to the present disclosure.

FIG. 5 is a first schematic view illustrating the package structure shown in FIG. 1, when formed, having a photonic device disposed therein according to the present disclosure.

FIG. 6 is a second schematic view illustrating the package structure shown in FIG. 1, when formed, having the photonic device disposed therein according to the present disclosure.

FIG. 7 is a schematic view illustrating the package structure shown in FIG. 1, when formed, being filled with a second filling material according to the present disclosure.

FIG. 8 is a schematic view illustrating the package structure shown in FIG. 3, when formed, being filled with the second filling material according to the present disclosure.

FIG. 9 is a schematic view illustrating the package structure shown in FIG. 1, when formed, having an outer covering layer formed thereon according to the present disclosure.

FIG. 10 is a flowchart of step S11 to step S16 of a method for manufacturing the package structure according to the present disclosure.

FIG. 11 is a flowchart of step S141 to step S142 of the method for manufacturing the package structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Embodiment

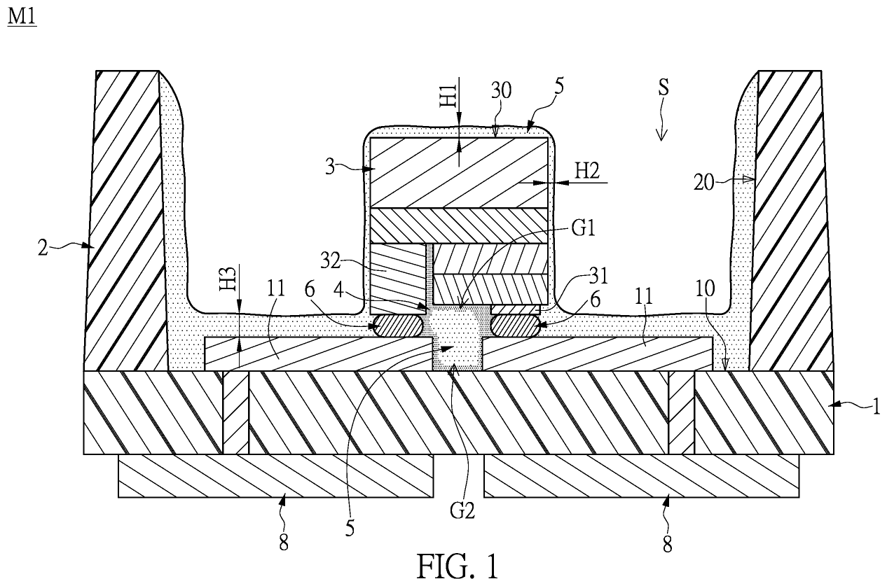

Referring to FIG. 1, a package structure M1 is provided in an embodiment of the present disclosure, which includes a substrate 1, a wall 2, and a photonic device 3. The wall 2 is disposed on the substrate 1, and a space S is formed between the wall 2 and the substrate 1. The photonic device 3 is located in the space S. The photonic device 3 is disposed on the substrate 1. The substrate 1 can include a ceramic substrate or a lead frame. In the present disclosure, the photonic device 3 is an ultraviolet C light emitting diode (UVC LED) chip, so that the package structure M1 is a UVC LED package structure. For example, the photonic device 3 is disposed on the substrate 1 in the form of a flip chip, but the present disclosure is not limited thereto. A height of the wall 2 is substantially equal to a distance between an upper surface 10 of the substrate 1 and a top surface of the photonic device 3. The photonic device 3 includes a p-contact 31 and an n-contact 32, and a gap G1 is defined between the p-contact 31 and the n-contact 32.

Furthermore, the substrate 1 includes two metal pads 11 that are disposed in the space S, and the photonic device 3 is disposed on the two metal pads 11. The p-contact 31 and the n-contact 32 are electrically connected to the two metal pads 11, respectively. The two metal pads 11 are positioned on one side of the substrate 1 and are electrically connected to an external electrode 8 positioned on another side of the substrate 1 through conductive posts. A groove G2 corresponding to the gap G1 is formed between the two metal pads 11; more specifically, the gap G1 and the groove G2 are communicated with each other to form a semi-enclosed space.

The package structure M1 further includes an inner covering layer 4 disposed in the gap G1 between the p-contact 31 and the n-contact 32. The inner covering layer 4 covers two opposite inner surfaces of the p-contact 31 and the n-contact 32, respectively. It is worth mentioning that the inner covering layer 4 also covers a surface of the groove G2, but the present disclosure is not limited thereto. The inner covering layer 4 can not only cover the two opposite inner surfaces of the p-contact 31 and the n-contact 32, respectively, and the surface of the groove G2, but also directly fill the gap G1 and the groove G2. In addition, the inner covering layer 4 can be made of an insulating material, such as fluorocarbon CₓF_{y}, which has a relatively better ductility, and an extension rate can be between 162% and 190%. For example, a chemical formula of fluorocarbon is CF₃—(CF₂—CFCF₂CF₂—O—CF—CF₂)ₙ—CF₃. In addition, in view of improving the luminous efficacy, the material of the inner covering layer 4 can also include high-refractive nanopowder made of materials such as zirconia (ZrO₂) or polytetrafluoroethylene, so as to increase the reflectivity.

In addition, as shown in FIG. 1, the photonic device 3 further includes a die substrate (not labeled in the figures), an n-type layer (not labeled in the figures, e.g., a cladding layer, an electron supply layer, a contact layer, and/or the like), an active layer (not labeled in the figures), and a p-type layer (not labeled in the figures, e.g., an electron blocking layer, a cladding layer, a hole supply layer, a contact layer, and/or the like). Specifically speaking, the p-type layer, the active layer, the n-type layer, and the die substrate can be stacked upon one other sequentially from bottom to top, as shown in FIG. 1. Moreover, the gap G1 has an interspace between the active layer, the p-type layer, and the n-contact 32. The inner covering layer 4 can be filled into the interspace of the gap G1 and cover a portion of each of the active layer, the p-type layer, and the n-contact 32.

In addition, the package structure M1 can also include an outer covering layer 5 covering an outer surface 30 of the photonic device 3. Furthermore, the outer covering layer 5 is disposed in the space S, and also covers the upper surface 10 of the substrate 1 and the inner surface 20 of the wall 2. In addition, a material of the outer covering layer 5 includes, but is not limited to, fluorocarbon. As shown in FIG. 1, when the outer covering layer 5 covers the upper surface 10 of the substrate 1, the inner surface 20 of the wall 2 and the outer surface 30 of the photonic device 3, thicknesses of the outer covering layer 5 can be different at each position. Specifically, a ratio between a thickness H1 of a top portion of the outer covering layer 5 that covers the outer surface 30 of the photonic device 3 and a thickness H2 of a side portion of the outer covering layer 5 that covers the outer surface 30 of the photonic device 3 is between 1.2 and 2.2. A ratio of a thickness H3 of a portion of the cover layer 5 covering the upper surface 10 of the substrate 1 to the thickness H1 of the top portion of the cover layer 5 that covers the outer surface 30 of the photonic device 30 is between 1 and 1.5. For example, the thickness H3 of the portion of the outer covering layer 5 that covers the upper surface 10 of the substrate 1 is substantially 30 micrometers (μm) on average, the thickness H2 of the side portion of the outer covering layer 5 that covers the outer surface 30 of the photonic device 3 is substantially 20 μm on average, and the thickness H1 of the top portion of the outer covering layer 5 that covers the outer surface 30 of the photonic device 3 is substantially 25 μm on average.

In addition, the package structure M1 can also include two die bonding adhesives 6, which are disposed between the p-contact 31 and one of the two metal pads 11, and between the n-contact 32 and another one of the two metal pads 11, respectively. The inner covering layer 4 is not only covered on the two opposite inner surfaces of the p-contact 31 and the n-contact 32, respectively, and the surface of the groove G2, but the inner covering layer 4 is also covered on inner surfaces of each of the two adjacent die bonding adhesives 6. In the present disclosure, the two die bonding adhesives 6 are made of highly thermal conductive materials having a thermal conductivity coefficient greater than 80. For example, each of the two die bonding adhesives 6 can be nano-silver or sintering silver, based on a total weight of the die bonding adhesive, the silver material in the die bonding adhesive 6 is 70 weight percent or more, but the present disclosure is not limited thereto.

Compared with conventional die bonding adhesives that usually adopt a gold-tin alloy as material, the die bonding adhesive 6 (i.e., each of the two die bonding adhesives 6) in the present disclosure is made of a material having silver of 70 wt % or more. An advantage of the die bonding adhesive 6 using a greater amount of silver material is that the silver material has a high thermal conductivity coefficient, and can considerably reduce a processing temperature. For example, when sintering silver is used as the die bonding adhesive 6, since the thermal conductivity coefficient of the sintering silver is greater than 100, the processing temperature can be reduced from 310° C. (i.e., when the gold-tin alloy is used for the conventional die bonding adhesive) to 200° C. In addition, another advantage of using sintering silver as the die bonding adhesive 6 is that the reflectivity of sintering silver is higher. Therefore, compared with a conventional UVC LED package structure where the gold-tin alloy is adopted as the die bonding adhesive, the UVC LED package structure of the present disclosure using sintering silver as the die bonding adhesive 6 has a brightness that is increased by 5% to 8%. Furthermore, compared with the conventional silver gel (i.e., 65 wt % to 68 wt % of silver) that can withstand a shear stress of substantially 1 kg, the die bonding adhesive 6 of the present disclosure can withstand a greater shear stress. For example, the die bonding adhesive 6 adopting nanosilver can have a shear stress larger than 2 kg. The die bonding adhesive 6 adopting sintering silver can have a shear stress of more than 5 kg, such that the chips are less likely to slide, and that the chips have a higher reliability.

On the other hand, in the package structure M1 of the present disclosure, the p-contact 31 and the n-contact 32 are insulated from each other through the inner covering layer 4 being filled in the gap G1 and the groove G2 to cover the two opposite inner surfaces of the p-contact 31 and the n-contact 32, respectively, and the surface of the groove G2. Therefore, formation of dangling bonds between the p-contact 31 and the n-contact 32 can be reduced, thereby preventing the silver migration effect caused by sintering silver being adopted as the die bonding adhesive 6, and preventing short circuits caused by the silver migration effect.

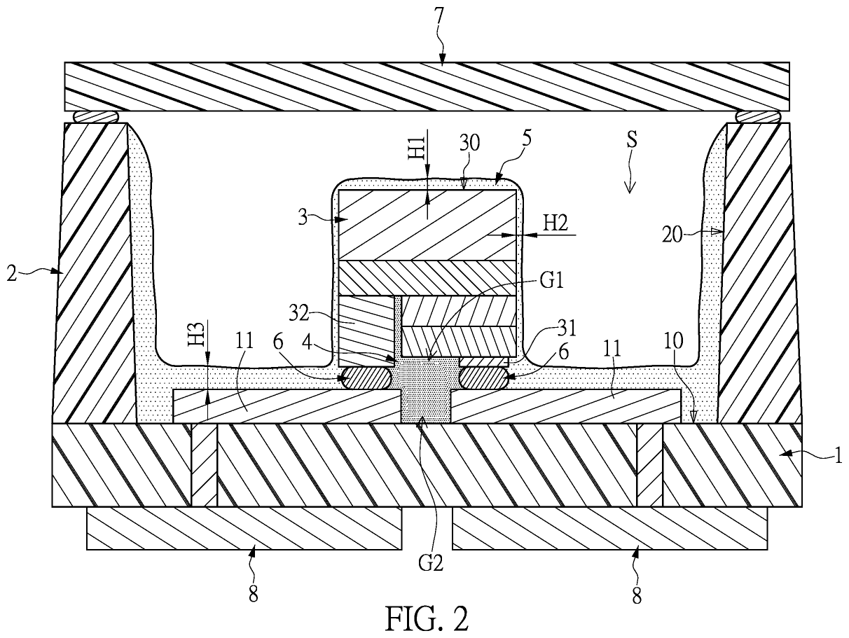

Referring to FIG. 2, the package structure of the present disclosure can further include a lens component 7 which can be stacked on the wall 2. UVC light enters a light sensor structure through the lens component 7 and is received by a light sensing component. It should be noted that, when UVC light having a relatively shorter wavelength enters the package structure M1 from the external environment, the UVC light is mainly received by the top surface of the photonic device 3. In addition, the present disclosure does not further limit a structure of the lens component 7. For example, the lens component 7 includes, but is not limited to, a flat lens, a spherical lens, or a Fresnel lens. The lens component 7 can be made of a material including quartz, fluorocarbon, or sapphire, but the present disclosure is not limited thereto.

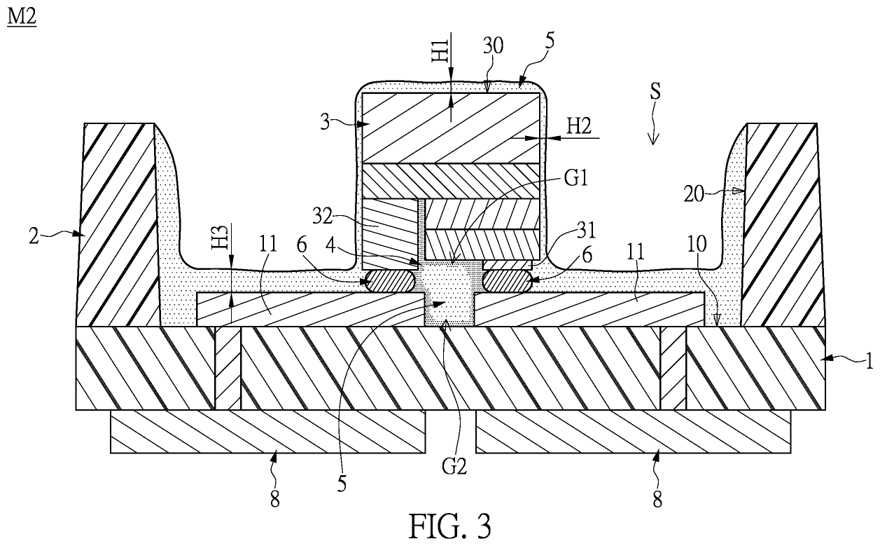

Referring to FIG. 3, which is a schematic view of a package structure in another implementation of the present disclosure. A package structure M2 of another embodiment is illustrated in FIG. 3, the differences between the package structure M2 and the package structure M1 shown in FIG. 1 is that the wall 2 of the package structure M2 is relatively short. A height of the wall 2 is between 40% and 60% of the height of the photonic device 3. Specifically, the height of the photonic device 3 indicates a distance between the upper surface 10 of the substrate 1 and the top surface of the photonic device 3, and the height of the wall 2 of the package structure M2 shown in FIG. 3 is 40% to 60% of the distance between the upper surface 10 of the substrate 1 and the top surface of the photonic device 3. The height of the wall 2 affects the thickness of where the outer covering layer 5 covers inside the package structure M2. For example, when the height of the wall 2 is between 40% and 60% of the height of the photonic device 3 (e.g., when the height of the wall 2 is 200 μm), the thickness H3 of the portion of the outer covering layer 5 that covers the upper surface 10 of the substrate 1 is substantially 25 μm on average, the thickness H2 of the side portion of the outer covering layer 5 that covers the outer surface 30 of the photonic device 3 is substantially 10 μm on average, and the thickness H1 of the top portion of the outer covering layer 5 that covers the outer surface 30 of the photonic device 3 is substantially 20 μm on average.

The present disclosure provides implementations of different heights of the wall 2, so that users can adjust the height of the wall 2 according to actual requirements. When the wall 2 is relatively taller (i.e., when the height of the wall 2 is substantially equal to the distance between the upper surface 10 of the substrate 1 between the top surface of the photonic device 3), a structural strength of the package structure can be increased. When the wall 2 is relatively shorter (i.e., when the height of the wall 2 is substantially 40% to 60% of the distance between the top surface 10 of the substrate 1 and the top surface of the photonic device 3), the light emitted by the photonic device 3 and then reflected by the wall 2 has a better reflection effect, and the brightness generated by light emitted by the UVC LED package structure can be further increased.

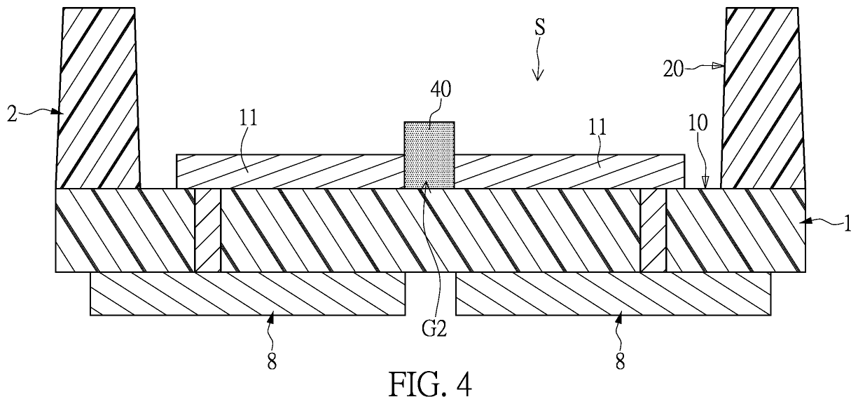

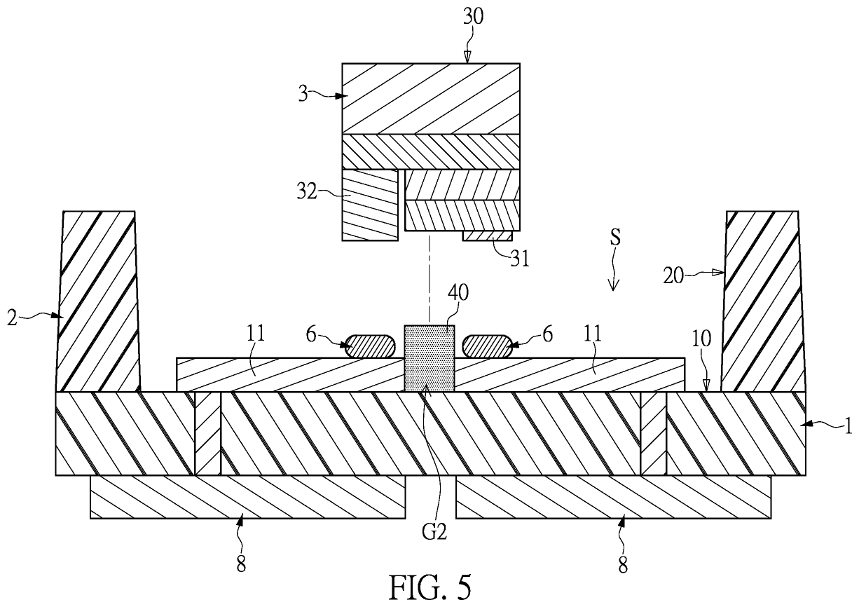

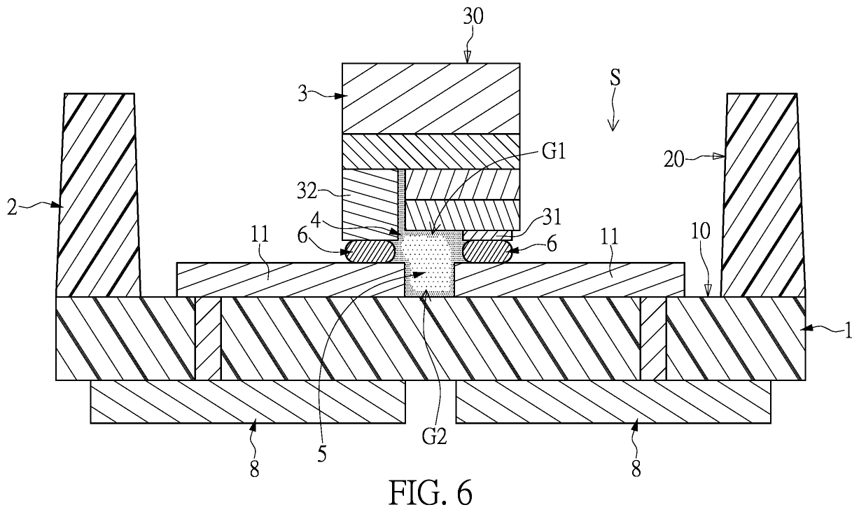

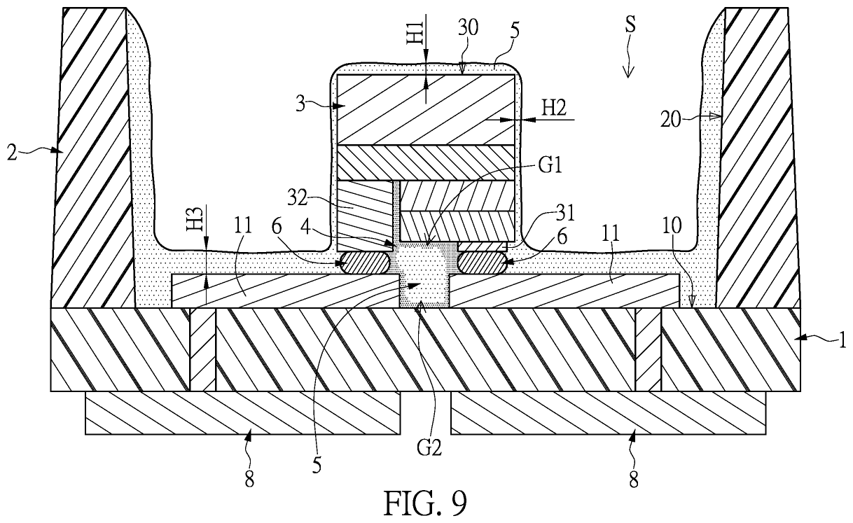

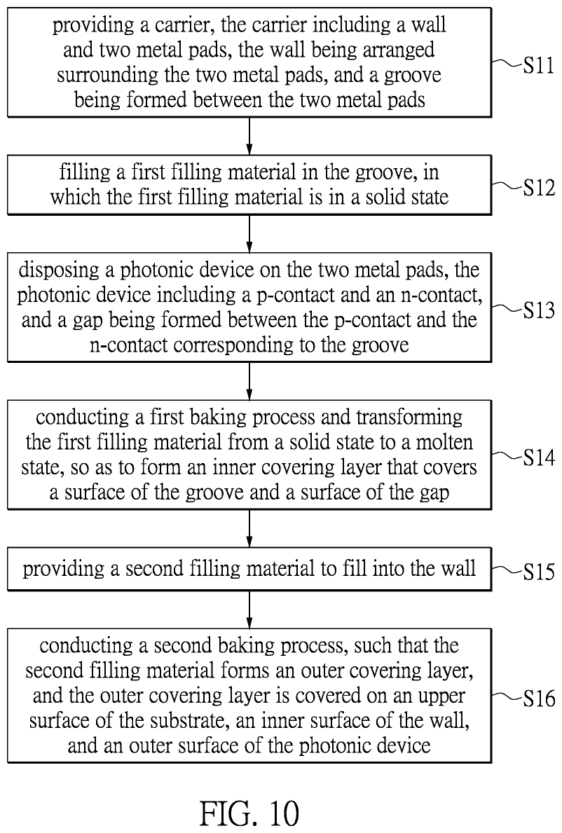

References are made to FIG. 4 to FIG. 10. FIG. 4 to FIG. 9 are schematic views illustrating steps of a method for manufacturing the package structure M1 of the present disclosure. FIG. 10 is a flowchart of step S11 to step S16 of the method for manufacturing the package structure M1 of the present disclosure. The method for manufacturing the package structure M1 and M2 is provided in the present disclosure, and the method at least includes the following steps:

Step S11: providing a carrier, the carrier including a wall 2 and two metal pads 11, the wall 2 being arranged surrounding the two metal pads 11, and a groove G2 being formed between the two metal pads 11.

Step S12: filling a first filling material 40 in the groove G2, in which the first filling material 40 is in a solid state.

Step S13: disposing a photonic device 3 on the two metal pads 11, the photonic device 3 including a p-contact 31 and an n-contact 32, and a gap G1 being formed between the p-contact 31 and the n-contact 32 corresponding to the groove G2.

Step S14: conducting a first baking process and transforming the first filling material 40 from a solid state to a molten state, so as to form an inner covering layer 4 that covers a surface of the groove G2 and a surface of the gap G1.

Step S15: providing a second filling material 50 to fill into the wall 2.

Step S16: conducting a second baking process, such that the second filling material 50 forms an outer covering layer 5, and the outer covering layer 5 is covered on an upper surface 10 of the substrate 1, an inner surface 20 of the wall 2, and an outer surface 30 of the photonic device 3.

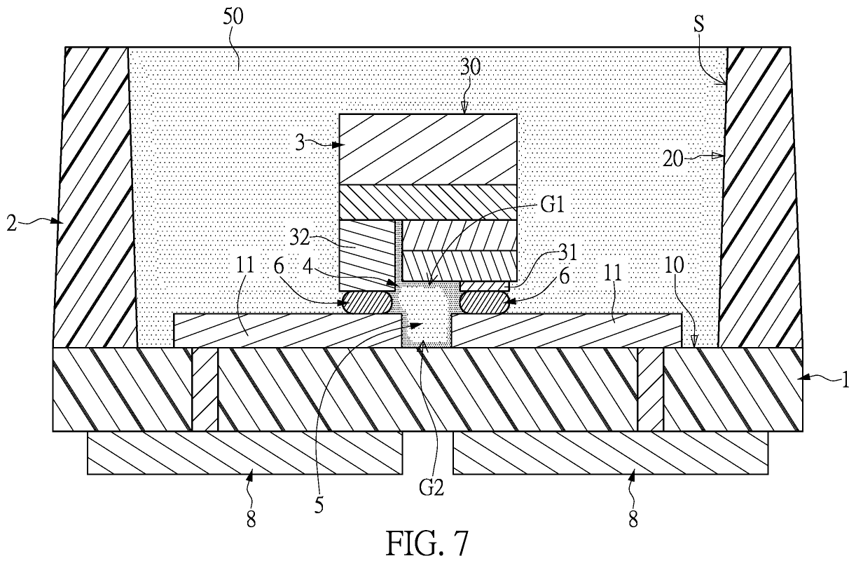

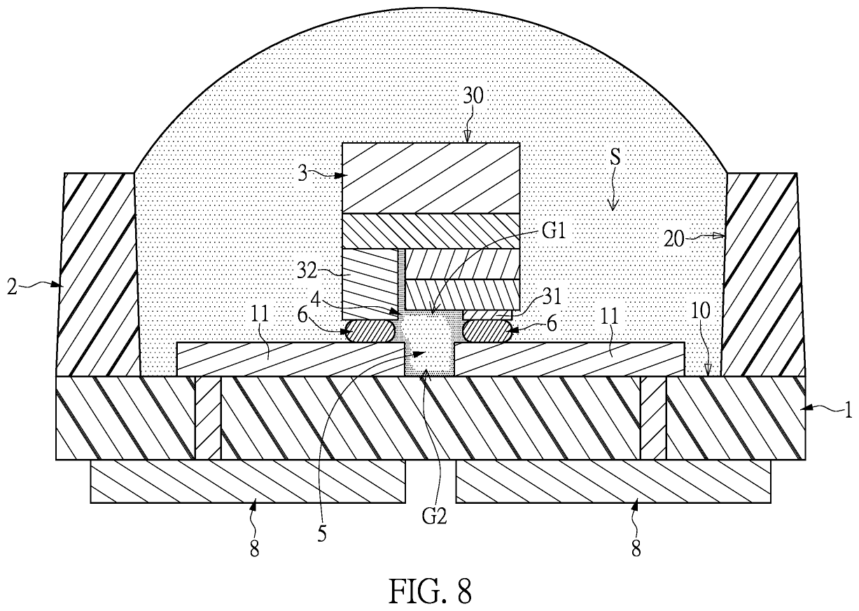

In step S11, specifically, the carrier mainly includes the substrate 1, the wall 2, and the two metal pads 11. The substrate 1 can include a ceramic substrate or a lead frame. The wall 2 is disposed on the substrate 1, and a space S is formed between the wall 2 and the substrate 1. The two metal pads 11 are disposed in the space S. The two metal pads 11 are positioned on one side of the substrate 1 and are electrically connected to the external electrode 8 positioned on another side of the two metal pads 11 through the conductive posts. It is worth mentioning that the method for manufacturing the package structure provided in the present disclosure is suitable for implementations of both the package structure M1 having the wall 2 that is relatively taller, and the package structure M2 having the wall 2 that is relatively shorter, as shown in FIG. 7 and FIG. 8.

In step S12, the first filling material 40 includes insulating materials, such as fluorocarbon, having a higher ductility and an extension rate between 162% and 190%. The top surface of the solid first filling material 40 slightly protrudes from the top surfaces of the two metal pads 11.

In step S13, the photonic device 3 is a UVC LED chip. Therefore, the package structure M1 is a UVC LED package structure. The first filling material 40 contacts the p-contact 31 and the n-contact 32. For example, the photonic device 3 can be disposed on the substrate 1 in the form of a flip chip. The gap G1 and the groove G2 are communicated with each other to form a semi-enclosed space. In addition, the package structure M1 also includes two die bonding adhesives 6, which are respectively disposed between the p-contact 31 and one of the two metal pads 11, and between the n-contact 32 and the another one of the two metal pads 11. The die bonding adhesive 6 (i.e., each of the two die bonding adhesives 6) includes silver material, and based on the total weight of the die bonding adhesive, the silver material in the die bonding adhesive 6 is 70 wt % or more. For example, the die bonding adhesive 6 can be nano-silver or sintering silver, but the present disclosure is not limited thereto.

In step S14, when a baking temperature of the first baking process reaches the melting point of the first filling material 40, the first filling material 40 in a molten state climbs from the position in contact with the p-contact 31 and the re-contact 32, and extends to form the inner covering layer 4 covering the two opposite inner surfaces of the p-contact 31 and the n-contact 32, respectively. The material of the inner coating layer 4 is identical to that of the first filling material 40, and the material includes, but is not limited to, for example, fluorocarbon, which has a better ductility and the extension rate between 162% and 190%. It is worth mentioning that the inner covering layer 4 can not only cover the two opposite inner surfaces of the p-contact 31 and the n-contact 32, respectively, and the surface of the groove G2, but also directly fill the gap G1 and the groove G2, and the present disclosure is not limited thereto. Furthermore, the inner covering layer 4 not only covers the two opposite inner surfaces of the p-contact 31 and the n-contact 32, respectively, and the surface of the groove G2, but also covers the two adjacent die bonding adhesives 6.

In step S15, the second filling material 50 is filled into the wall 2, and preferably filled to a point exceeding the height of the photonic device 3, and even more preferably filling the entire space S. The second filling material 50 is in a liquid state and contains volatile organic compounds, and the material of the second filling material 50 includes, but is not limited to, fluorocarbon. In addition, as shown in FIG. 7, the height of the wall 2 is substantially equal to the distance between the upper surface 10 of the substrate 1 and the top surface of the photonic device 3, and the top surface of the second filling material 50 is flush with or slightly sunken in from a top side of the wall 2. The method for manufacturing of the present disclosure is also suitable for the implementation of the package structure M2 having the wall 2 that is relatively shorter. As shown in FIG. 8, the height of the wall 2 is substantially 40% to 60% of the distance between the upper surface 10 of the substrate 1 and the top surface of the photonic device 3. At this time, when the second filling material 50 is filled in the space S, a top of the second filling material 50 protrudes from the top side of the wall 2 and is substantially a convex shape.

In step S16, after baking the second filling material 50 at a processing temperature between 180° C. and 200° C., and removing the volatile organic compounds, the outer coating layer 5 is formed. The ratio between the thickness H1 of the top portion of the outer coating layer 5 that covers the outer surface 30 of the photonic device 3 to the thickness H2 of the side portion of the outer coating layer 5 that covers the outer surface 30 of the photonic device 3 is between 1.2 and 2.2. The ratio of the thickness H3 of the portion of the outer coating layer 5 that covers the upper surface 10 of the substrate 1 to the thickness H1 of the top portion of the outer coating layer 5 that covers the outer surface 30 of the photonic device 3 is between 1 and 1.5.

In addition, before conducting the second baking process, a deflux procedure is performed. The deflux procedure is mainly used to clean flux of the die bonding adhesive 6. Removing the flux can increase the reflection effect of the photonic device 3 and further increase the brightness of the light emitted by the photonic device 3.

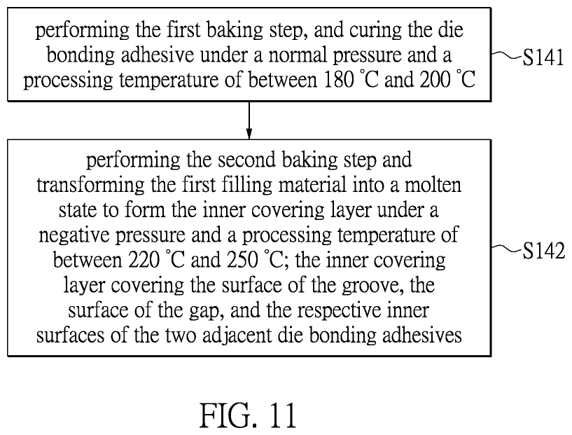

In addition, referring to FIG. 11, step S14 further includes:

Step S141: performing the first baking step, and curing the die bonding adhesive 6 under a normal pressure and a processing temperature of between 180° C. and 200° C.

Step S142: performing the second baking step and transforming the first filling material 40 into a molten state to form the inner covering layer 4 under a negative pressure and a processing temperature of between 220° C. and 250° C. The inner covering layer 4 covers the surface of the groove G2, the surface of the gap G1, and the respective inner surfaces of the two adjacent die bonding adhesives 6.

### Beneficial Effects of the Embodiment

One of the beneficial effects of the present disclosure is that the package structure provided in the present disclosure can reduce a formation of the dangling bonds and prevent the metal migration effect from occurring through technical solutions of “the inner covering layer 4 covering the two opposite inner surfaces of the p-contact 31 and the n-contact 32, respectively” and “the outer covering layer 5 covering the upper surface 10 of the substrate 1, the inner surface 20 of the wall 2 and the outer surface 30 of the photonic device 3”.

Another one of the beneficial effects of the present disclosure is that the method for manufacturing the package structure M1 and M2 provided in the present disclosure can reduce a formation of the dangling bonds and prevent the metal migration effect from occurring through technical solutions of “conducting the first baking process and transforming the first filling material 40 from a solid state to a molten state to form the inner covering layer 4, the inner covering layer 4 covering the surface of the groove G2 and the surface of the gap G1” and “conducting the second baking process, such that the second filling material 50 forms the outer covering layer 5, and the outer covering layer 5 is covered on the upper surface 10 of the substrate 1, the inner surface 20 of the wall 2, and the outer surface of the photonic device 3”.

Furthermore, compared with conventional die bonding adhesives that usually adopt the gold-tin alloy as material, the die bonding adhesive 6 (i.e., each of the two die bonding adhesives 6) in the present disclosure is made of a material having silver of 70 wt % or more. An advantage of the silver material being adopted by the die bonding adhesive 6 is that the silver material has a high thermal conductivity coefficient, and can considerably reduce a processing temperature. For example, when sintering silver is used as the die bonding adhesive 6, since the thermal conductivity coefficient of the sintering silver is greater than 100, the processing temperature can be reduced from 310° C. when the gold-tin alloy is used for the conventional die bonding adhesive, to 200° C. In addition, another advantage of using sintering silver as the die bonding adhesive 6 is that the reflectivity of sintering silver is higher. Therefore, compared with a conventional UVC LED package structure where the gold-tin alloy is used as the die bonding adhesive, the UVC LED package structure of the present disclosure using sintering silver as the die bonding adhesive 6 has a brightness that is increased by 5% to 8%.

On the other hand, in the package structure M1 and M2 of the present disclosure, the p-contact 31 and the n-contact 32 are insulated from each other through the inner covering layer 4 being filled in the gap G1 and the groove G2 to cover the two opposite inner surfaces of the p-contact 31 and the n-contact 32, respectively, and the surface of the groove G2. Therefore, formation of dangling bonds between the p-contact 31 and the n-contact 32 can be reduced, thereby preventing the silver migration effect caused by sintering silver being adopted as the die bonding adhesive 6, and preventing short circuits caused by the silver migration effect.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A package structure, comprising:
a substrate;
a wall disposed on the substrate, a space being formed between the substrate and the wall;
a photonic device accommodated in the space, the photonic device being disposed on the substrate, the photonic device including a p-contact and an n-contact, and a gap being defined between the p-contact and the re-contact;
an inner covering layer disposed in the gap between the p-contact and the n-contact; and
an outer covering layer covered on an upper surface of the substrate, an inner surface of the wall, and an outer surface of the photonic device.

2. The package structure according to claim 1, wherein the substrate includes two metal pads, the photonic device is disposed on the two metal pads, and the p-contact and the n-contact are respectively electrically connected to the two metal pads; wherein a groove is formed between the two metal pads corresponding to the gap, and the inner covering layer covers two opposite inner surfaces of the p-contact and the n-contact, respectively, and a surface of the groove.

3. The package structure according to claim 2, further comprising two die bonding adhesives that are respectively disposed between the p-contact and one of the two metal pads, and between the n-contact and another one of the two metal pads, and the inner cover layer is covered on inner surfaces of the two die bonding adhesives.

4. The package structure according to claim 3, wherein each of the two die bonding adhesives includes a silver material, and based on a total weight of the die bonding adhesive, the silver material in the die bonding adhesive is 70 weight percent or more.

5. The package structure according to claim 3, wherein a shear stress of each of the two die bonding adhesives is greater than 2 kg.

6. The package structure according to claim 1, wherein a ratio of a thickness of a top portion of the outer covering layer that covers the outer layer of the photonic device to a thickness of a side portion of the outer covering layer that covers the outer layer of the photonic device is between 1.2 and 2.2.

7. The package structure according to claim 6, wherein a ratio of a thickness of a portion of the outer covering layer that covers the upper surface of the substrate to the thickness of the top portion of the outer covering layer that covers the outer layer of the photonic device is between 1 and 1.5.

8. The package structure according to claim 1, wherein a height of the wall is between 40% and 60% of that of the photonic device.

9. The package structure according to claim 1, wherein an extension rate of the inner covering layer is between 160% and 192%.

10. The package structure according to claim 1, wherein the inner covering layer is made of fluorocarbons.

11. The package structure according to claim 1, wherein the outer covering layer is made of fluorocarbons.

12. The package structure according to claim 1, further comprising a lens component stacked on the wall.

13. A method for manufacturing a package structure, comprising:
providing a carrier, the carrier including a wall and two metal pads, the wall being arranged surrounding the two metal pads, and a groove being formed between the two metal pads;
filling a first filling material in the groove, wherein the first filling material is in a solid state;
disposing a photonic device on the two metal pads, the photonic device including a p-contact and an n-contact, and a gap being formed between the p-contact and the n-contact corresponding to the groove;
conducting a first baking process and transforming the first filling material from a solid state to a molten state, so as to form an inner covering layer that covers a surface of the groove and a surface of the gap;
providing a second filling material to fill into the wall; and
conducting a second baking process, such that the second filling material forms an outer covering layer, and the outer covering layer is covered on an upper surface of the substrate, an inner surface of the wall, and an outer surface of the photonic device.

14. The method according to claim 13, wherein the photonic device is disposed on the two metal pads through two die bonding adhesives, respectively, the inner covering layer is covered on an inner surface of each of the two die bonding adhesives, each of the two die bonding adhesives includes a silver material, and based on a total weight of the die bonding adhesive, the silver material in the die bonding adhesive is 70 weight percent or more.

15. The method according to claim 14, wherein the first baking process includes a first baking step and a second baking step, the first baking process has a baking temperature between 180° C. and 200° C., and the second baking step has a baking temperature between 220° C. and 250° C. under a negative pressure.

16. The method according to claim 14, wherein the second baking process has a baking temperature between 180° C. and 200° C.

17. The method according to claim 13, wherein a height of the wall is between 40% and 60% of that of the photonic device, so that a top of the second filling material protrudes from the top side of the wall and is substantially a convex shape when the second filling material is filled into the wall.

18. The method according to claim 13, wherein a top surface of the first filling material protrudes from a top surface of the two metal pads, and is in contact with the p-contact and the n-contact.

19. The method according to claim 13, wherein an extension rate of the inner covering layer is between 160% and 192%.

20. The method according to claim 13, wherein the first filling material and the second filling material include fluorocarbons.
